(19) United States
(12) Patent Application Publication
(10) Pub. No.: US 2018/0302187 A1
(43) Pub. Date: Oct. 18, 2018

(54) TRANSCEIVER FOR ASYNCHRONOUS DATA TRANSMISSION OVER A NOISY CHANNEL

(71) Applicant: YAMAR ELECTRONICS LTD., TEL AVIV (IL)

(72) Inventor: YAIR MARYANKA, TEL AVIV (IL)

(21) Appl. No.: 15/769,094

(22) PCT Filed: Oct. 17, 2016
(86) PCT No.: PCT/IB2016/056224

§ 371 Date: Apr. 18, 2018

(30) Foreign Application Priority Data
Oct. 19, 2015 (EP) 15190476.0

(51) Int. Cl. H04L 1/00; H04L 7/04; H04B 3/54; H04B 1/38; H04J 3/06

(52) U.S. Cl. CPC H04L 1/0083; H04L 1/0084; H04L 1/009; H04L 1/0091; H03M 13/25; H04B 3/54; H04B 1/38; H04J 3/06; H04L 7/04

(57) ABSTRACT

A method of asynchronous transmission over a noisy channel includes the following steps: providing a data frame having at least one start bit, payload data and at least one stop bit, the data frame having a predetermined number of bits; forming a signaling preamble having a predetermined length by using at least said start and stop bit periods of the data frame; building a processed data frame by attaching the signaling preamble to the payload data, the processed data frame having the same predetermined number of bits; and modulating the processed data with a signaling modulation scheme and transmitting the modulated processed data over the noisy channel. The method can be advantageously implemented for data transmission over DC and/or AC power lines, for instance in vehicles or cars. Despite the noise on the data channel the data transmission is robust and there is no need for further error correction codes.

### BACKGROUND OF THE INVENTION

The present invention relates to communications over data channels, especially over DC and/or AC power lines, and more specifically to a method and a transceiver for asynchronous data transmission over a noisy channel.

### STATE OF THE ART

It is known that electronic devices and system must communicate via data buses to other electronic devices or systems. For instance a Universal Asynchronous Receiver Transmitter (UART) is used in many circumstances to enable device, for instance an integrated circuit or microprocessor, to receive and send data from and to other electronic devices.

To ensure that receiver and transmitter are able to identify payload data a START/STOP-bit synchronization system may be implemented. Said synchronization system inserts a start bit at the head of a data item and a stop bit at the tail of the data item, allowing a receiving device to recognize the head and tail of the transmitted data item without transmitting any sync signal. The data item starting with the start bit and ending with the stop bit may be referred to as a “frame” or “data frame”. A state in which no data is transmitted through a communication channel is referred to as an “idle” state (logical value “1”). In response to detection of a start bit, that is usually the logical value “0”, the receiving device which is in the idle state detects the start of frame, and start the sampling of the data item. The receiving device continues the sampling for a predetermined data length, and returns to the idle state in response to detection of the stop bit, that is usually logical value “1”. Accordingly the receiver or the receiving device may receive subsequent frames in an analogous manner. Further it is conceivable that transmitting device and receiving device may share information such as bit rate, data length, stop bit length, and error detection (parity bit and CRC, channel quality or the like) in advance.

If data frames are to be conveyed over noisy channels, like for instance power lines or the like, it may happen that the receiver will not be able to properly detect the beginning of the data frame, which is the start bit, leading to synchronization problems between the transmitter and the receiver. Furthermore, for improved performance in noise, the data may be protected against errors. The usual methods of protecting a message or data frame are to implement for instance forward error correction codes or the like.

EP 1292060 B1 discloses a signaling method between a plurality of devices interconnected on a noisy channel. To avoid redundant error correction codes the method of EP 1292060 B1 proposes the use of combinations of phase changes or phase shifts to ensure proper transmission of payload data over the power line, hereafter this kind of transmission of data over data channels will be named signaling.

The known error protection codes are inefficient for protecting short data like for instance only one byte of data especially on noisy channels like power lines, for instance DC and/or AC power lines. Due to the noise on the power line channel, for instance a DC and/or AC power line channel, data degradation may arise leading to an inefficient transmission on this specific data channel.

### OBJECT OF THE PRESENT INVENTION

Therefore, an object of the present invention is to provide a robust transmission method of data independently of its data length, which can be used especially on noisy transmission channels. Furthermore another object of the present invention is to provide a transceiver able to communicate with short messages, and able to overcome the problems of the existing devices.

### SUMMARY OF THE PRESENT INVENTION

According to the present invention a method of asynchronous transmission over a noisy channel is provided. The method comprises at least following steps: providing a data frame, said data frame including at least one start bit, payload data and at least one stop bit, said data frame having a predetermined number of bits, forming a signaling preamble having a predetermined length by using at least said start and stop bit periods of said data frame, building a processed data frame by attaching said signaling preamble to said payload data, said processed data frame having the same predetermined number of bits, and modulating said processed data by using a signaling modulation scheme and transmitting said modulated processed data over said noisy channel.

The method according to the present invention receives a serial data stream comprising data frames which may correspond to the UART standard in one embodiment. The data frame is used for asynchronous data transmission wherein no common clocks are needed. The data frame has a predetermined number of bits N which corresponds to the original data length of the original data frame. According to the invention a signaling preamble may be formed, the preamble making use of at least the bit period of the included start and stop bit periods in the original data frame. Thus the entire data length will remain unchanged which in turn means that the present invention will be compatible with already implemented solutions for instance.

According to the invention a processed data frame will be built by attaching a signaling preamble to the payload data by keeping the data length unchanged as in the original data. Thereafter the processed data will be modulated prior transmission on the noisy channel, whereby the signaling preamble will serve as a fingerprint for the receiver to identify that valid data was received or transmitted, accordingly. Thus the signaling preamble serves as an identification signal for valid data, wherein the signaling method of EP 1292060 B1 of the applicant, which is incorporated by reference, may be used according to one embodiment.

The method according to the present invention can be advantageously be implemented for data transmission over DC and/or AC power lines, like for instance in vehicles or cars. Despite of the noise occurred on the data channel the method transmits the data in a robust manner and no need for further error correction codes are needed. It is imaginable that the present invention may be implemented on the basis of AC power lines or even within wireless RF systems, wherein short data lengths especially are to be conveyed.

### EMBODIMENTS OF THE INVENTION

According to one embodiment of the present invention the preamble corresponds to a signaling synchronization sequence of the data frame, wherein the synchronization sequence comprises a predetermined bit length of at least the number of the used start and stop bits. Thereby the bit periods of the start and stop bits can be used to generate the signaling synchronization sequence for the payload leading to a robust data transmission method with no need for error correction codes. Thus in one embodiment the signaling synchronization sequence may be two bits long which are in turn modulated on a carrier to be conveyed over the noisy channel. This signaling fingerprint will in turn be compared with valid fingerprints at the receiver to identify valid data.

According to one embodiment the signaling preamble may be formed on the basis of payload data within the data frame. Hence more than two bit periods to generate the preamble may be used leading to a better robustness while transmitting the data over the noisy channel. On the basis of stored preamble sequences at the receiver it can be determined which value the original data bit of the payload data had. This step is necessary because at least one bit period of the payload data was used for generating the signaling preamble or pattern. Nevertheless due to longer preamble sequences the robustness in terms of data errors on the noisy channel can be significantly increased.

In one embodiment the signaling modulation scheme is a phase shift key (PSK) modulation scheme. Especially the modulation technique as disclosed in EP 1292060 B1 shows satisfying results during transmission of short data lengths over a noisy channel, especially on a DC and/or AC power line.

The forming step comprises shifting said stop bit adjacent to the start bit of said data frame. Thus the processed data frame will have the same data length leading to a compatible data format, which may be used in existing transmission systems for instance. Therefore the method according to the present invention is upward and/or downward compatible.

According to an embodiment of the present invention demodulating of a received signaling data frame is provided, wherein sampling of the received data will be executed and thereafter the sampled data can be entered into a shift register. Thus a quick processing and storing of received data on the receiver site may be performed. The stored data in the register can in turn be easily processed later if needed.

According to one embodiment comparing of the sampled data with reference signaling data patterns stored in a register on the receiver side is provided, and further detecting if a valid signaling preamble was received. By means of this operations proper encoding and reconstructing of valid sent data can be ensured. By using more than one signaling data patterns for the comparison the robustness of the transmission method of the present invention may be increased.

In case of a positive detection of a valid signaling preamble building said original data frame may be performed. Therefore further processing of the received valid data can follow.

The data frame is a universal asynchronous receiver/transmitter interface (UART) data type, RS232, RS485, LIN, CAN, SPI, MIL-Std-1553 data type or the like. Therefore the method according to the invention can be implemented in various transmission systems in a flexible manner.

According to another aspect of the present invention a transceiver for asynchronous sending and/or receiving of data over a noisy channel is provided. The transceiver comprises a register for storing a data frame with a predetermined data length, a processor for processing said data frame by forming a signaling preamble sequence. The processor further comprises a module for generating the signaling preamble sequence on the basis of data bits of the data frame, wherein the processed data frame has the aforementioned predetermined length. The transceiver furthermore comprises a modulator for modulating the processed data frame leading to modulated signaling data and a sender to send the modulated signaling data over a noisy channel.

This transceiver architecture is adapted to execute the operational sequence of the method of the present invention. The transceiver architecture may be implemented in a standard integrated circuit like a FPGA, a DSP or the like.

According to one embodiment the transceiver further comprises receiver to receive the modulated signaling data, a demodulator to demodulate the received modulated signaling data; a comparator to compare the preamble sequence with at least one valid preamble signaling sequence stored in a valid sequence register and a module for reconstructing said original data frame. Hence the transceiver can be used in an universal manner as a receiver and/or as a transmitter.

The modulator may be a phase shift key modulator. This technique allows robust transmission and encoding of sent data especially on noisy channels.

In embodiments of the present invention, the modulator unit may furthermore be adapted for encoding the serial bit stream, for instance the processed data frame, using for example AM, FM, QPSK, FSK, MSK, ASK or similar techniques, or a combination of such techniques.

The accompanying figures are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts. The drawings described are only schematic and are non-limiting. In the drawings, the size of some of the elements may be exaggerated and not drawn on scale for illustrative purposes. The dimensions and the relative dimensions do not correspond to actual reductions to practice of the invention.

### SHORT DESCRIPTION OF THE FIGURES

The invention is explained in further detail, by way of example and with reference to the accompanying drawings wherein:

FIG. 1 shows the UART encoding scheme;

FIG. 2 shows an operational sequence of the method (operational diagram) according to the present invention;

FIG. 3 depicts the signaling principle according to the present invention on the basis of an UART encoding scheme;

FIG. 4 schematically shows the transmission path according to the present invention;

FIG. 5 schematically shows the corresponding receiving path of the present invention; and

FIG. 6 discloses one embodiment of a transceiver according to the present invention.

### DETAILED DESCRIPTION

In the following detailed description, reference is made to the accompanying drawings, which form a part hereof, and in which is shown by way of illustration specific embodiments in which the invention may be practiced. In this regard, directional terminology, such as “top,” “bottom,” “front,” “back,” etc., is used with reference to the orientation of the figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

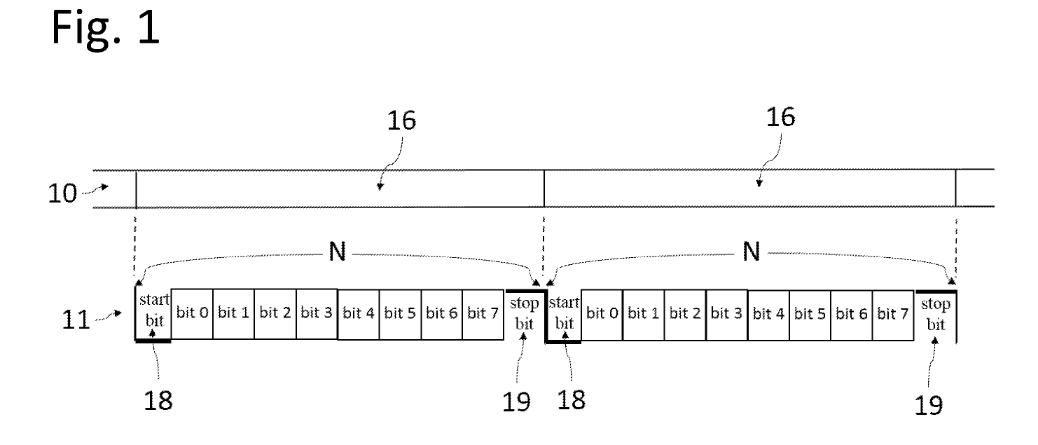

FIG. 1 shows a usual UART encoding scheme. The UART provides a means of sending and receiving bytes serially over a transmission channel, like for instance a wire or AC and/or DC power line at a specific data rate, namely baud rate. A data stream 10 is shown comprising a number of bytes 11, and the UART encoded data stream 16 is shown below. At the sending end each data byte 16 is enhanced with a start bit 18, stop bit 19 and may also be configured with a parity bit or checksum bit for instance which are not shown below. Each bit is transmitted serially at the pace of the baud rate clock. At the receiving site, the transition between the start bit 18 and stop bit 19 synchronizes the baud rate clock and the received data bits are sampled with the baud rate clock upon reception. The start bit 18, stop bit 19 and any parity bits (not shown) are removed by a processor and the data byte 16 may be placed in a dynamic register or buffer.

This processing of the data bytes is usually embedded in a UART port hardware in a transceiver or the like. The UART interface allows a simple transmission of payload data wherein no coding or decoding is needed. Over noisy channels like for instance AC and/or DC power lines the start bit and stop bit of the data frame may not be detected properly leading to synchronization problems on the receiver for instance. Therefore for detect data errors a message payload checksum mechanism may be provided so that a message check sum is added to each message. This checksum is then validated at the receiving end to check the message integrity. A checksum result different from the expected will cause a message to be rejected. However synchronization problems are not able to be detected by error detection and/or correction codes.

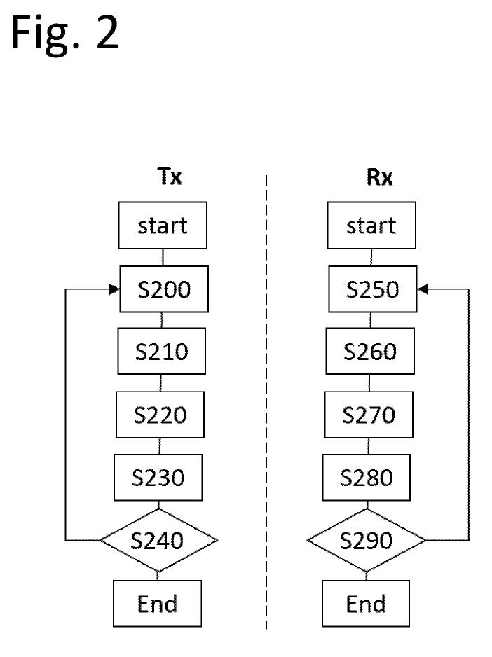

FIG. 2 shows an operational sequence of the method according to the present invention. In a first step S200 the operational sequence may start by providing a data frame including at least one start bit 18, payload data and at least one stop bit 19, said data frame 16 having a predetermined number of bits N. Such a data frame structure is shown with reference to FIG. 1, wherein one start bit and one stop bit are used. After the data frame 16, which for example may be a UART data frame but also other data format able to be used for an asynchronous data transmission are conceivable to be processed according to the method of the present invention, was provided a signaling preamble may be formed in step S210. The forming step S210 forms the signaling preamble by using the bit periods of the start and stop bit therefore keeping the whole data length N unchanged. After the signaling preamble was formed in step S210, building of a processed data frame S220 will be performed, wherein again the data length of the processed data frame will be identical with the original length of the provided data frame above in step S200. Thus the method can be used in already implemented data transmission systems where the used data lengths were already fixed.

After a processed data frame was provided modulating of said processed data follows according to a modulating step S230. The modulation scheme used may correspond to the technique disclosed in EP 1292060 B1 of the applicant, which is herewith incorporated by reference. The modulated signal is thereafter transmitted S240 over a channel, i.e. a noisy DC and/or AC power line wire for instance in an automobile to a receiver Rx which is in turn connected to the power line system for instance. The method on the transmitter site Tx of the present invention may be restarted if a next original data frame will be provided.

FIG. 2 shows on the right side the operational sequence on the receiver site according to a possible embodiment of the present invention. During a receiving step S250 a processed data stream, which was generated on the transmitter Tx site according to the present invention, may be further processed. The received data stream belongs to a serial data stream, which has to be encoded on the receiver site. Next demodulating of the received data in step S260 may be performed. Therein the modulated radio frequency signal is demodulated, whereby the base band signal is extracted.

According to the present invention a comparing step S270 is executed wherein the received signaling data frame is compared with reference signaling data patterns stored in a register at the receiver for instance. If a valid signal was detected the CPU in the receiver for instance may rebuild S280 the sent original data and the received data may further be processed. During a decisional step S290 it may be identified if valid data is present and in case of a positive identification the receiving method may stop. If false data was received the receiving method may further be executed in a recursive manner whereby a new modulated data frame may be processed until valid data was encoded.

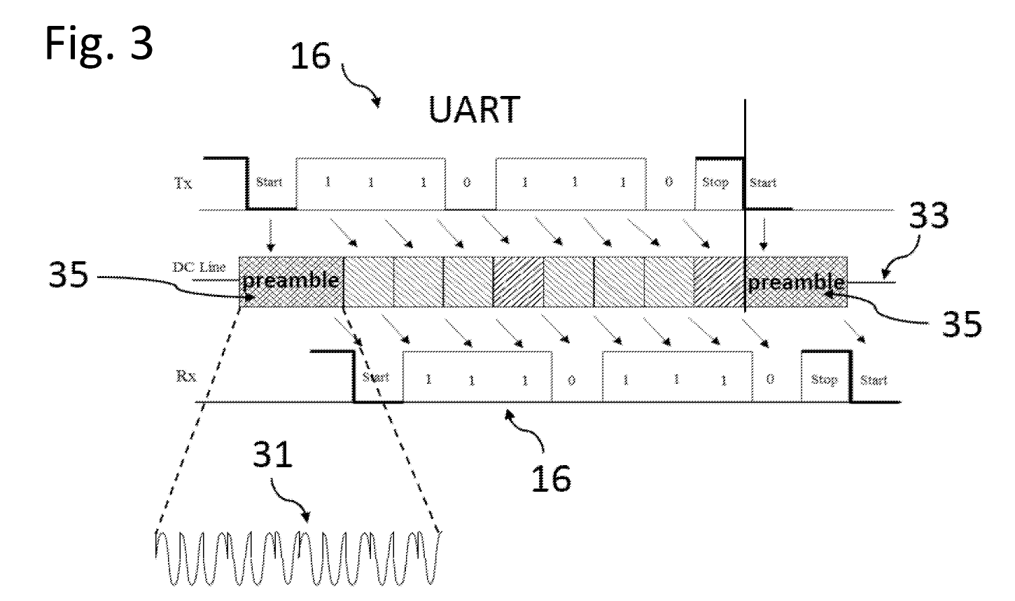

FIG. 3 schematically shows the principle of the present invention. By the way of example a UART data frame was used comprising one start bit, one stop bit and eight bit of payload data, that is the data lengths is ten bits. According to the present invention a signaling data preamble is generated by keeping the data frame length unchanged, that is according to this embodiment ten bits. It should be understood that different data frame lengths are implementable within the scope of the present invention.

In order to be able to synchronize a single byte of data, a synchronization sequence, herein preamble sequence is required at the beginning of the byte. Said preamble distinguishes between ordinary noise that exist over the power line and the start of the byte. A longer preamble sequence ensures better detection of the unique preamble sequence within the noise occurred in the transmission channel, i.e. DC and/or AC power line. The overall length of the byte cannot be changed because the number of bytes in a message can be infinite. Therefore, the synchronization preamble length determines the byte robustness to noise and interference.

The method according to the present invention suggest to use both the start and stop bits periods of the asynchronous byte as the preamble period, followed by the modulated data bits, keeping the entire byte duration unchanged, which is schematically shown with reference to FIG. 3. On the DC line for instance, the processed data frame 33 is shown comprising a signaling preamble 35 having a length of two bits corresponding to the minimum amount of start and stop bits in the UART frame. With reference 31 the modulated preamble sequence 35 is shown wherein a PSK modulation technique with phase changes was implemented.

For the robust transmission of the data over the noisy channel a PSK modulation scheme may be implemented. At the bottom of FIG. 3 the modulated preamble is schematically shown. It should be noted that the remaining bits of the processed data frame will also be modulated prior the transmission over the noisy channel. For the sake of simplicity only the modulated preamble is shown.

Furthermore, if more than these two bits period may be required for the preamble, it is conceivable to generate two different preamble sequences. The receiver will try to detect both sequences within the noisy channel. If the first sequence is detected, the first data bit will be considered as “1”. If the second sequence is detected, the first data bit will be considered as “0”. Furthermore, if longer preamble period may be needed, four different preamble sequences can be used for the first two bits of data and so on. Thus the method according to the present invention can be adapted on the basis of the channel transmission quality. That is, the better the channel transmission is the fewer bits for the signaling preamble are needed.

According to a further embodiment the entire byte period of the UART data frame may be divided into two sub periods, where the first sub period is used as preamble and the second sub period is used to transfer the entire data bits. The determination of the necessary length of these sub periods is a balance that depends on the demodulation receiver performance in the expected noisy channel and the required bit rate.

The method is applicable to many existing data types such as RS232, RS485, LIN, CAN, SPI, MIL-Std-1553 or the like.

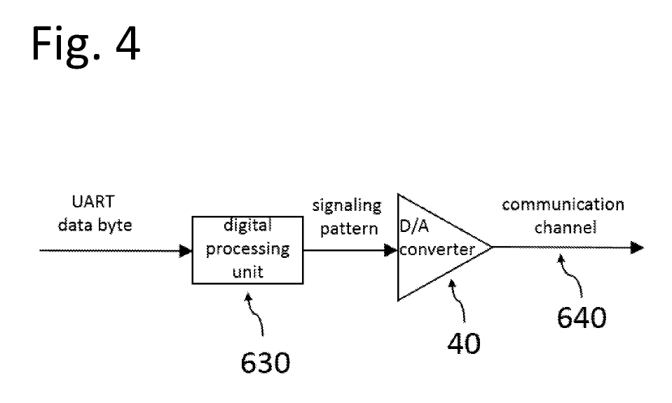

With reference to FIG. 4 the transmitter according to the present invention is schematically shown. The transmitting side receives the UART data byte. Upon detection of the start bit 18, the digital processing unit or CPU 630 starts to transmit the preamble sequence 35. During this period, the data bits are entered into the digital processing unit 630 and signaling patterns for the payload data are generated according to the entered bits (“0” or “1”). The signaling patterns are converted into an analog signal form by means of a digital to analog converter. The converted data will be in turn transmitted over the DC power line 604 according to one embodiment. It should be noted the communication channel 604 may also be a AC power line connection or the like.

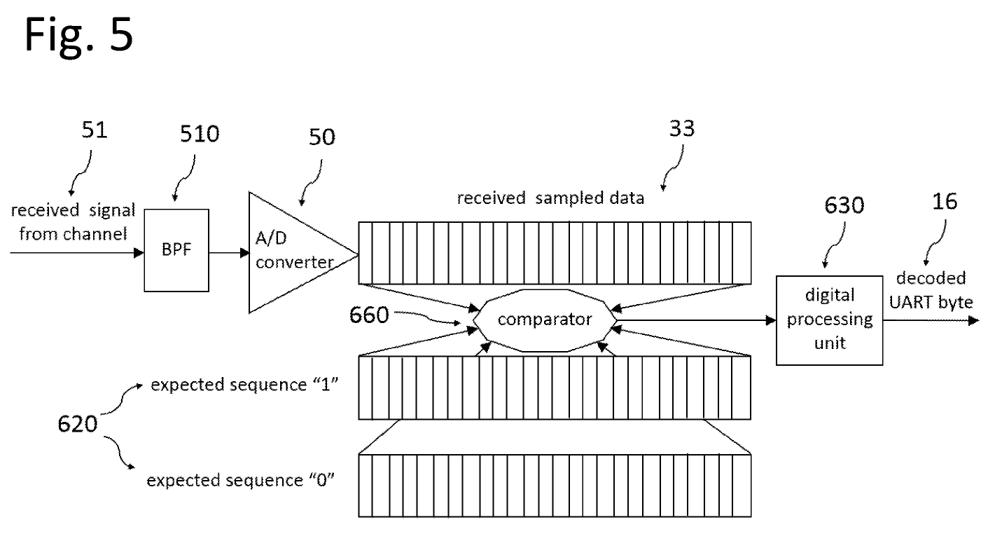

FIG. 5 shows schematically a receiver according to the present invention that detects sequence of two possible expected sequences (“0” or “1”). Same solution can be used for only one preamble sequence or more sequences. Furthermore, similar circuit can be used to detect also the data pattern bits. The received modulated signal 51, pass through band pass filter 510 and is sampled at high speed by an analog to digital converter 50. The sampled data enter into a shift register 620 where each sampled data is compared with an expected sequence (one or more) that is stored in a memory 62a. If the result of the entire compared shift register values are gathered by the digital processing unit 630. If the calculated values are close enough to the value of the expected sequence, (one or more) the digital processing unit 630 start to detect the rest of the expected data bytes and output the decoded data in the original UART byte format as entered on the transmitting side.

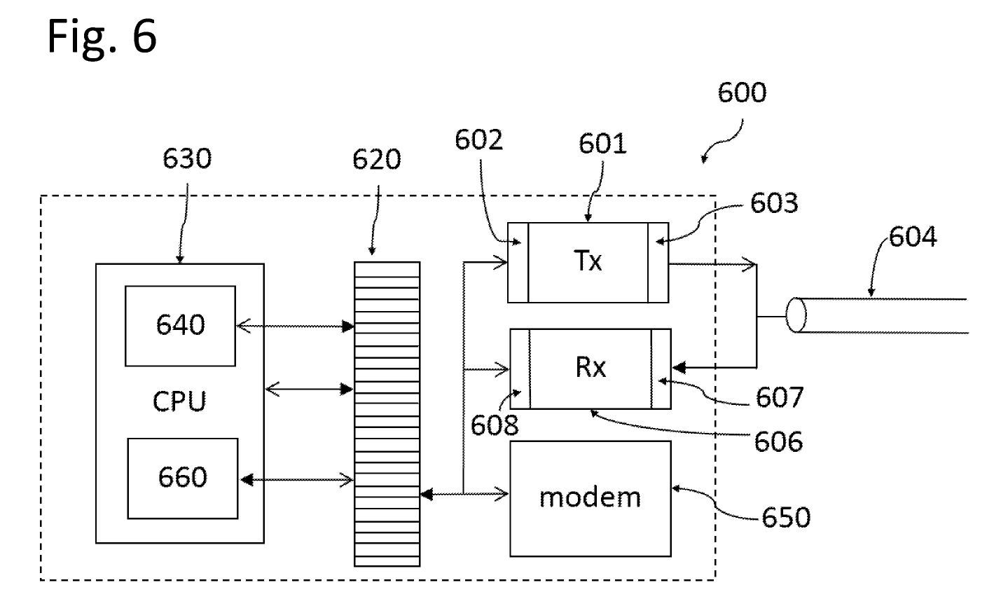

FIG. 6 shows a possible embodiment of the transceiver 600 according to the present invention. Referring to FIG. 6, a transmitter 601 for transmitting data over a power supply line 604 and a receiver 606 for receiving data transmitted over the power supply line 604 according to embodiments of the present invention are illustrated. According to one exemplary embodiment the transmitter 601 and the receiver 606 are implemented as one device or apparatus as a transceiver 600, but also two functional blocks or separated apparatuses for transmitting and receiving are conceivable.

The transmitter 601 and the receiver 606 are functionally connected, e.g. the transmitter and receiver are apparatuses that complement each other and may work together. For example, the transmitter and receiver may be combined into a modem for data communication.

The transmitter 601 comprises a signal interface or port 602 for receiving a serial bit stream. For example, the serial bit stream may correspond to the processed data frame as explained with reference to FIG. 2, wherein the method according to an embodiment of the present invention is disclosed. The transceiver operating on the basis of the inventive method may provide a robust hardware and software solution for data exchange between different components in vehicles for instance.

The transmitter 601 also comprises a power line interface or port 603 for sending a signal over a power supply line 604, especially a DC power line or wire. The signal interface 602 may be implemented to receive a serial bit stream in form of a processed data frame according to the present invention. The power line connection interface 603 may be adapted for transmitting a signal over a power supply line 604 of the vehicle.

The transmitter 601 further comprises a modulator 605 for generating the modulated signal on the basis of the processed data. The modulator 605 is adapted to encode the processed serial bit stream, e.g. the serial bit stream received via the local signal port 602 and processed according to the method of the present invention described with reference to FIG. 2, into an original signal. The modulation technique may be a phase shift key modulation as disclosed in EP 1292060 B1 of the applicant.

The modulator 605 may implement different modulation techniques such as: amplitude modulation (AM), frequency modulation (FM) or phase modulation (PM) or the like. However, the modulator 605 may also implement digital modulation techniques, such as amplitude shift keying (ASK), frequency shift keying (FSK), minimum shift keying (MSK), or more complex techniques like quadrature phase shift keying (QPSK), or quadrature amplitude modulation (QAM) or the like.

According to an embodiment the modulator 605 is implemented to function according to the modulation technique as disclosed in EP 1292060 B1 of the applicant leading to a robust transmission of short data over noisy channels, especially over the DC power line 604 according to one embodiment.

The receiver 606 within the transceiver 600 may comprise two interfaces 608 and 607 which are interconnected in an analogous manner with reference to the transmitter 601 as shown in FIG. 6.

Further the transceiver 600 comprises a central processing unit 630 or a CPU which is adapted to control the operation of the included modules. The CPU 630 is connected with a register device 620 which may be implemented as a static or dynamic register for instance, but other storage techniques are conceivable. Within the register 620 a valid data register 620a (not shown) may be implemented containing for instance a list of valid signaling preambles which are used for encoding of valid data which was received via the communication channel 604.

The transceiver 600 according to the present invention comprises a module for generating 640 a signaling preamble sequence on the basis of data bits of said data frame, wherein the processed data frame comprises an unchanged number of bits N. The generating module 640 may be implemented as software code running on the CPU 630 but other implementation techniques are conceivable.

For receiving and encoding the data a comparator module or unit 660 may be implemented which compares the received signaling preamble with predetermined valid signaling preambles within a register 620a (not shown) within the transceiver 600. If the comparison step identifies a match valid data was received which can be processed further.

The modem device 650 with reference to FIG. 6 may be implemented to modulate and/or demodulate date which has to be sent and received over the power line 604. The functionality of the modem 650 is not explained in detail herein and should be clear for a person skilled in the art of data communication.

For the sake of simplicity not all connections within the transceiver 600 are depicted, but it should be clear that all units might be interconnected by means of the CPU 630 for instance. According to a further embodiment the transceiver may be implemented on a FPGA for instance wherein suitable firmware code is embodied to operate according to the method of the present invention.

It is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features.

Thus, the scope of the expression “a device comprising means A and B” should not be limited to devices or modules consisting only of components A and B. It means that with respect to the present invention, the only relevant components of the device are A and B.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

Similarly it should be appreciated that in the description of exemplary embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of this invention.

Although specific embodiments have been illustrated and described herein, it will be appreciated by those of ordinary skill in the art that a variety of alternate and/or equivalent implementations may be substituted for the specific embodiments illustrated and described without departing from the scope of the present invention. This application is intended to cover any adaptations or variations of the specific embodiments discussed herein. Therefore, it is intended that this invention be limited only by the claims and the equivalents thereof.

1-15. (canceled)

16. A method of asynchronous transmission of data over a noisy channel, the method comprising:
providing a data frame having at least one start bit, payload data and at least one stop bit, the data frame having a predetermined number of bits;
forming a signaling preamble having a predetermined length by using at least the start and stop bit periods of the data frame;
building a processed data frame by attaching the signaling preamble to the payload data, the processed data frame having the predetermined number of bits; and
modulating the processed data by using a signaling modulation scheme and transmitting the modulated processed data over the noisy channel.

17. The method according to claim 16, wherein the signaling preamble corresponds to a signaling synchronization sequence of the data frame, the synchronization sequence having a predetermined bit length of at least a number of the start and stop bits.

18. The method according to claim 16, wherein the signaling preamble is formed on a basis of the payload data within the data frame.

19. The method according to claim 16, wherein the signaling modulation scheme is a phase shift key modulation scheme.

20. The method according to claim 16, wherein the forming step comprises shifting the stop bit to a position adjacent the start bit of the data frame.

21. The method according to claim 16, which further comprises receiving the processed data at a receiver.

22. The method according to claim 21, which further comprises demodulating the signaling data frame received at the receiver by sampling the data and entering sampled data into a shift register.

23. The method according to claim 22, which further comprises comparing the sampled data with reference signaling data patterns stored in a register on a receiver side, and determining whether a valid signaling preamble was received.

24. The method according to claim 23, which further comprises, upon detecting a valid signaling preamble, building the original data frame.

25. The method according to claim 16, wherein the data frame is a data type selected from the group consisting of universal asynchronous receiver/transmitter interface data type, RS232, RS485, LIN, CAN, SPI, and MIL-Std-1553 data type.

26. A transceiver for asynchronous sending and/or receiving of data over a noisy channel, the transceiver comprising:
a register for storing a data frame with a predetermined data length;
a processor connected to said register and configured for processing the data frame by forming a signaling preamble sequence, said processor including a module for generating the signaling preamble sequence based on data bits of the data frame, a processed data frame having the predetermined data length;
a modulator for modulating the processed data frame to form modulated signaling data; and
a transmitter configured for transmitting the modulated signaling data over the noisy channel.

27. The transceiver according to claim 26, further comprising:
a receiver configured to receive the modulated signaling data;
a demodulator configured to demodulate the modulated signaling data received by said receiver;
a comparator configured to compare the signaling preamble sequence with at least one valid signaling preamble sequence stored in a valid sequence register; and
a module for reconstructing the original data frame.

28. The transceiver according to claim 26, wherein said modulator is a phase shift key modulator.

29. The transceiver according to claim 26, wherein the noisy channel is a power line.

30. The transceiver according to claim 29, wherein the noisy channel is a DC and/or AC power line connection.

31. A transceiver for asynchronous sending and/or receiving of data over a noisy channel, the transceiver comprising a central processing unit configured and programmed to execute the method according to claim 16.
